(19) United States
(12) Patent Application Publication
(10) Pub. No.: US 2024/0152056 A1
(43) Pub. Date: May 9, 2024

(54) METHOD FOR TREATING A SUBSTRATE

(71) Applicant: SEMES CO., LTD., Cheonan-si (KR)

(72) Inventors: Sang Gun LEE, Seoul (KR); Ki Hoon CHOI, Cheonan-si (KR); Hyun YOON, Seoul (KR); Seung Un OH, Cheonan-si (KR); Jin Yeong SUNG, Hwaseong-si (KR); Jang Jin LEE, Seoul (KR); Tae Shin KIM, Suwon-si (KR)

(73) Assignee: SEMES CO., LTD., Cheonan-si (KR)

(21) Appl. No.: 18/502,628

(22) Filed: Nov. 6, 2023

(30) Foreign Application Priority Data
Nov. 7, 2022 (KR) 10-2022-0147298

(51) Int. Cl. G03F 7/42; G03F 7/40

(52) U.S. Cl. CPC G03F 7/423; G03F 7/40

(57) ABSTRACT

The inventive concept provides a substrate treating method. The substrate treating method includes supplying a liquid to a substrate; and heating the substrate after the supplying the liquid, and wherein the supplying the liquid includes: supplying a first liquid to the substrate; and supplying a second liquid which is different from the first liquid to a substrate to which the first liquid is supplied, and wherein the second liquid is supplied as a test to the substrate and a contact angle between the second liquid which is supplied and the substrate is measured to determine a degree of hydrophilization of the substrate, and a supply mechanism of the second liquid supplied to the substrate is determined based on the degree of hydrophilization of the substrate which is determined, before the supplying the second liquid is performed.

### CROSS-REFERENCE TO RELATED APPLICATIONS

A claim for priority under 35 U.S.C. § 119 is made to Korean Patent Application No. 10-2022-0147298 filed on Nov. 7, 2022, in the Korean Intellectual Property Office, the entire contents of which are hereby incorporated by reference.

### BACKGROUND

Embodiments of the inventive concept described herein relate to a substrate treating method, more specifically, a substrate treating method for heating a substrate.

A photolithography process for forming a pattern on a wafer includes an exposing process. The exposing process is a preliminary operation for cutting a semiconductor integrated material attached to the wafer into a desired pattern. The exposing process may have various purposes, such as forming a pattern for etching and forming a pattern for an ion implantation. The exposing process uses a mask, which is a kind of ‘frame’, to draw a pattern with a light on the wafer. If the light is exposed to the semiconductor integrated material on the wafer, such as a photoresist on the wafer, chemical properties of the photoresist change according to the pattern by the light and the mask. If a developer is supplied to the photoresist which chemical properties have changed according to the pattern, the pattern is formed on the wafer.

In order to accurately perform the exposing process, the pattern formed on the mask must be precisely manufactured. It should be checked whether the pattern is formed to satisfy the required process conditions. A large number of patterns are formed in one mask. Accordingly, it takes a lot of time for an operator to inspect all of the large number of patterns in order to inspect one mask. Accordingly, a monitoring pattern capable of representing one pattern group including a plurality of patterns is formed on the mask. In addition, an anchor pattern capable of representing a plurality of pattern groups is formed on the mask. The operator may estimate an amount of patterns included in one pattern group through an inspection of the monitoring pattern. In addition, the operator may estimate an amount of patterns formed on the mask through an inspection of the anchor pattern.

In addition, in order to increase an inspection accuracy of the mask, it is preferable that critical dimensions of the monitoring pattern and the anchor pattern are the same. A critical dimension correction process for precisely correcting critical dimensions of patterns formed on the mask is additionally performed.

FIG. 1 shows a normal distribution of a first critical dimension CDP1 of the monitoring pattern of the mask and a second critical dimension CDP2 of the anchor pattern before the critical dimension correction process is performed during a mask manufacturing process. In addition, the first critical dimension CDP1 and the second critical dimension CDP2 have a size smaller than a target critical dimension. Before the critical dimension correction process is performed, the critical dimension CD of the monitoring pattern and the anchor pattern is intentionally deviated. And, by additionally etching the anchor pattern in the critical dimension correction process, the critical dimensions of the two patterns are made the same. If the anchor pattern is etched more than the monitoring pattern in a process of additionally etching the anchor pattern, the critical dimension of the patterns formed on the mask cannot be accurately corrected due to a difference between the monitoring pattern and the anchor pattern. When additionally etching the anchor pattern, a precise etching of the anchor pattern must be accompanied.

While performing a process before performing the critical dimension correction process, the mask is hydrophobized. More specifically, the mask has a hydrophobicity due to an oxide formed on the mask. If an etchant is supplied to the mask to locally etch the anchor pattern formed on the mask, an affinity with the hydrophobized mask is reduced. Accordingly, the etchant is not uniformly coated on the mask, and even if the anchor pattern is later locally heated, the anchor pattern is not precisely etched. In addition, a degree of hydrophilization varies for each mask which performs the critical dimension correction process. That is, the degree of hydrophilization varies from mask to mask. If a mechanism for supplying the etchant to masks with different degrees of hydrophilization is applied in the same way, the degree of which the etchant is coated to each mask may be different. In this case, since the etching degree of the anchor pattern is different for each mask, a uniformity of the process is reduced.

### SUMMARY

Embodiments of the inventive concept provide a substrate treating method for precisely etching a specific region of a substrate.

Embodiments of the inventive concept provide a substrate treating method for precisely etching a specific region of a substrate by evenly coating an etchant on a substrate.

Embodiments of the inventive concept provide a substrate treating method for flexibly applying a supply mechanism of an etchant based on a degree of hydrophilization of a substrate.

The technical objectives of the inventive concept are not limited to the above-mentioned ones, and the other unmentioned technical objects will become apparent to those skilled in the art from the following description.

The inventive concept provides a substrate treating method. The substrate treating method includes supplying a liquid to a substrate; and heating the substrate after the supplying the liquid, and wherein the supplying the liquid includes: supplying a first liquid to the substrate; and supplying a second liquid which is different from the first liquid to a substrate to which the first liquid is supplied, and wherein the second liquid is supplied as a test to the substrate and a contact angle between the second liquid which is supplied and the substrate is measured to determine a degree of hydrophilization of the substrate, and a supply mechanism of the second liquid supplied to the substrate is determined based on the degree of hydrophilization of the substrate which is determined, before the supplying the second liquid is performed.

In an embodiment, the supply mechanism includes at least one of a supply time of the second liquid supplied to the substrate, a supply position of the second liquid supplied to the substrate, or a discharge angle of the second liquid.

In an embodiment, the discharge angle of the second liquid is changed depending on an angle of a nozzle with respect to a top surface of the substrate, and the discharge angle of the second liquid is adjusted according to the supply position of the second liquid to change the supply mechanism.

In an embodiment, the supply time of the second liquid is adjusted depending on the discharge angle of the second liquid to change the supply mechanism.

In an embodiment, the supplying the first liquid supplies the first liquid to the substrate to hydrophilize a hydrophobized substrate.

In an embodiment, the substrate is a mask, and the mask has a first pattern which is formed within a plurality of cells and a second pattern which is formed outside of a region at which the cells are formed, and the heating the substrate includes heating the second pattern between the first pattern and the second pattern by irradiating a laser to the second pattern.

In an embodiment, a critical dimension of the first pattern is larger than a critical dimension of the second pattern, before the second liquid is supplied to the substrate.

In an embodiment, the critical dimension of the first pattern and the critical dimension of the second pattern match within an error range, after the heating the substrate.

In an embodiment, a chamber suppling the first liquid and a chamber supplying the second liquid are different from each other.

In an embodiment, the second liquid is supplied to a substrate which has stopped rotating in the supplying the second liquid.

In an embodiment, the substrate treating method further includes supplying a rinsing liquid to a rotating substrate to clean the substrate.

In an embodiment, the first liquid includes a sulfuric acid, and the second liquid includes an etchant for etching a pattern formed on the substrate.

The inventive concept provides a mask treating method. The mask treating method includes hydrophilizing a mask by supplying a first liquid; etching a specific region of the mask; and cleaning the mask, and wherein the etching the specific region includes: supplying a second liquid which is different from the first liquid to the mask; and heating the specific region by irradiating a laser to the specific region of the mask to which the second liquid is supplied, and wherein a supply mechanism of the second liquid which is supplied to the mask is determined based on a contact angle between the second liquid which is supplied to the mask and the mask, at the supplying the second liquid.

In an embodiment, the supply mechanism includes a supply time of the second liquid supplied to the mask, a supply position of the second liquid supplied to the mask, and/or a discharge angle of the second liquid.

In an embodiment, a degree of hydrophilization of the mask is determined based on the contact angle, and as the degree of hydrophilization which is determined is smaller, the supply time of the second liquid increases to change the supply mechanism.

In an embodiment, a degree of hydrophilization of the mask is determined based on the contact angle, and as the degree of hydrophilization which is determined is smaller, the supply position of the second liquid is moved toward a center of the mask to change the supply mechanism.

In an embodiment, a degree of hydrophilization of the mask is determined based on the contact angle, and as the degree of hydrophilization which is determined is smaller, the discharge angle of the second liquid is increased to change the supply mechanism.

In an embodiment, the mask has a first pattern which is formed within a plurality of cells and a second pattern which is formed outside of a region at which the cells are formed, and the heating the specific region includes heating the second pattern between the first pattern and the second pattern by irradiating a laser to the second pattern.

In an embodiment, a critical dimension of the first pattern is larger than a critical dimension of the second pattern before the etching the specific region, and the critical dimension of the first pattern corresponds to the critical dimension of the second pattern after the etching the specific region.

The inventive concept provides a substrate treating method for treating a substrate having a first pattern and a second pattern which is different from the first pattern. The substrate treating method includes supplying a first liquid to the substrate to hydrophilize the substrate; supplying a second liquid to the substrate; locally heating the second pattern by irradiating a laser to the second pattern; and supplying a rinsing liquid to the substrate, and wherein the supplying the first liquid is performed in a first chamber, the supplying the second liquid, the locally heating the second pattern, and the supplying the rinsing liquid are performed at a second chamber which is different from the first chamber, a critical dimension of the first pattern is larger than a critical dimension of the second pattern before the supplying the second liquid, and the second pattern is etched so the critical dimension of the first pattern and the critical dimension of the second pattern are matched within an error range after the locally heating the second pattern, the second liquid is supplied as a test to the substrate and a contact angle between the second liquid which is supplied and the substrate is measured to determine a degree of hydrophilization of the substrate, and a supply mechanism of the second liquid supplied to the substrate is determined based on the degree of hydrophilization of the substrate which is determined, before the supplying the second liquid is performed, and the supply mechanism includes at least one of a supply time of the second liquid supplied to the substrate, a supply position of the second liquid supplied to the substrate, or a discharge angle of the second liquid.

According to an embodiment of the inventive concept, a specific region of a substrate may be precisely etched.

According to an embodiment of the inventive concept, a specific region of a substrate may be precisely etched by evenly coating an etchant on the substrate.

According to an embodiment of the inventive concept, a supply mechanism of an etchant may be flexibly applied based on a degree of hydrophilization of a substrate.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a normal distribution of a critical dimension of a monitoring pattern and a critical dimension of an anchor pattern.

FIG. 2 is a plan view schematically illustrating a substrate treating apparatus according to an embodiment.

FIG. 3 is a view of a substrate according to an embodiment as seen from above.

FIG. 4 is a cross-sectional view schematically illustrating a first chamber according to an embodiment.

FIG. 5 is a cross-sectional view schematically illustrating a second chamber according to an embodiment.

FIG. 6 is a cross-sectional view schematically illustrating the second chamber seen from above according to an embodiment.

FIG. 7 is a cross-sectional view of an optical module according to an embodiment, seen from a side.

FIG. 8 is a cross-sectional view of the optical module according to an embodiment seen from above.

FIG. 9 is a flowchart of a substrate treating method according to an embodiment.

FIG. 10 is a graph schematically illustrating a supply position of a second liquid on the substrate according to an embodiment.

FIG. 11 is a graph showing correlations between the supply position of the second liquid, a discharge angle of the second liquid, a supply amount of the second liquid, and a supply time of the second liquid according to an embodiment.

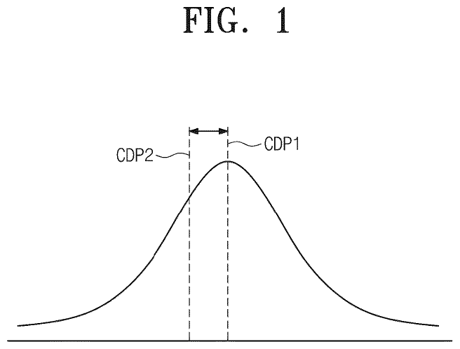

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

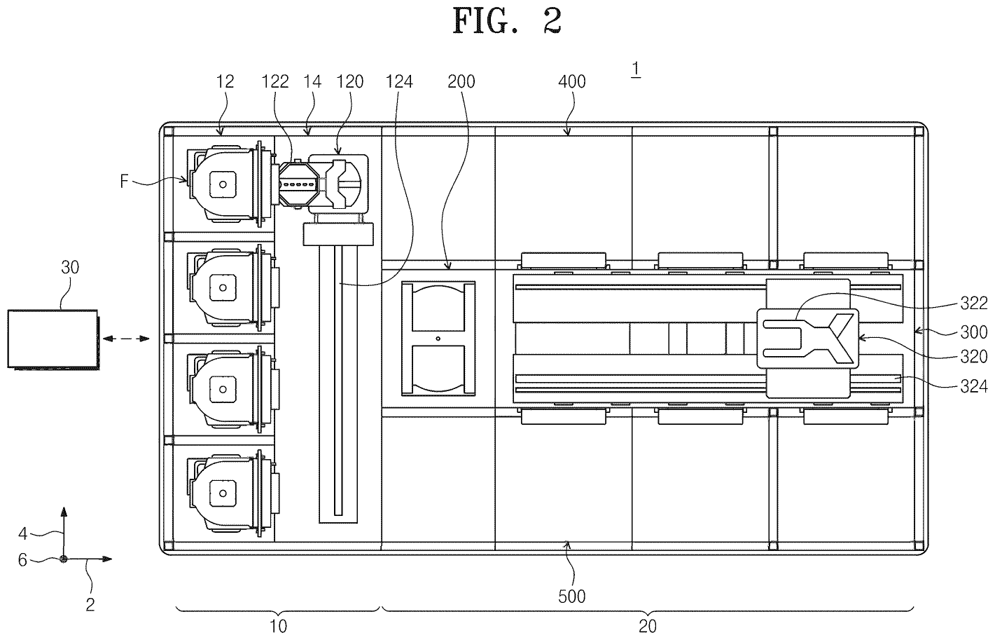

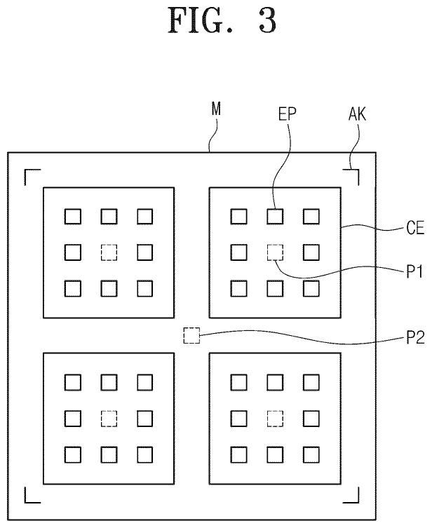

FIG. 2 is a plan view schematically illustrating a substrate treating apparatus according to an embodiment. FIG. 3 is a view of a substrate according to an embodiment as seen from above.

The substrate treating apparatus 1 includes an index module 10, an index module 20, a treating module 20, and a controller 30. According to an embodiment, the index module 10 and the treating module 20 may be disposed in a direction. Hereinafter, a direction in which the index module 10 and the treating module 20 are disposed is defined as a first direction 2. Also, when seen from above, a direction perpendicular to the first direction 2 is defined as a second direction 4, and a direction perpendicular to a plane including both the first direction 2 and the second direction 4 is defined as a third direction 6. For example, the third direction 6 may be a direction perpendicular to the ground.

The index module 10 transfers the substrate M. More specifically, the index module 10 transfers the substrate M between the container F in which the substrate M is stored and the treating module 20. The index module 10 has a lengthwise direction parallel to the second direction 4.

The index module 10 has a load port 12 and an index frame 14. A container F in which the substrate M is stored is mounted on the load port 12. The load port 12 may be disposed on an opposite side of the treating module 20 based on the index frame 14. A plurality of load ports 12 may be provided. The plurality of load ports 12 are arranged in a line along the second direction 4. The number of load ports 12 may increase or decrease according to a process efficiency and footprint conditions of the treating module 20.

The container F may be a sealed container such as a front opening unified pod (FOUP). The container F may be placed in the load port 12 by means of transfer (not shown) such as an overhead transfer, an overhead conveyor, or an automatic guided vehicle, or by an operator.

The index frame 14 has a transfer space for transferring the substrate M. An index robot 120 and an index rail 124 are disposed in the transfer space of the index frame 14. The index robot 120 transfers the substrate M between an index module 10 and a buffer unit 200 to be described later. The index robot 120 has a plurality of index hands 122. The substrate M is placed on the index hand 122. The index hand 122 may forwardly and backwardly move, rotate around the third direction 6 as an axis, and move along the third direction 6. Each of the plurality of index hands 122 may be spaced apart parallel to the third direction 6. Each of the plurality of index hands 122 may move independently.

The index rail 124 has a lengthwise direction parallel to the second direction 4. The index robot 120 is placed on the index rail 124, and the index robot 120 forwardly and backwardly moves along the index rail 124.

The controller 30 may control components included in the substrate treating apparatus 1. The controller 30 may comprise a process controller consisting of a microprocessor (computer) that executes a control of the substrate treating apparatus 1, a user interface such as a keyboard via which an operator inputs commands to manage the substrate treating apparatus 1, and a display showing the operation situation of the substrate treating apparatus 1, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The treating module 20 may include a buffer unit 200, a transfer frame 300, a first chamber 400, and a second chamber 700.

The buffer unit 200 has a buffer space. The buffer space functions as a space at which a substrate M taken into the treating module 20 and a substrate M taken out from the treating module 20 temporarily stay.

The buffer unit 200 is disposed between the index frame 14 and the transfer frame 300. The buffer unit 200 is positioned on a side of the transfer frame 300. A plurality of slots (not shown) on which the substrate M is placed are installed inside the buffer unit 200. The plurality of slots (not shown) are spaced apart from each other in the vertical direction.

The buffer unit 200 has a front face and a rear face which are open. The front face may be a surface facing the index frame 14. The rear face may be a surface facing the transfer frame 300. The index robot 120 may approach the buffer unit 200 through the front face, and the transfer robot 320 to be described later may approach the buffer unit 200 through the rear face.

The transfer frame 300 provides a space for transferring the substrate M between the buffer unit 200 and the chambers 400 and 700. The transfer frame 300 has a lengthwise direction horizontal to the first direction 2. The chambers 400 and 700 are disposed on a side of the transfer frame 300. The transfer frame 300 and the chambers 400 and 700 are disposed in the second direction 4. According to an embodiment, the chambers 400 and 700 may be disposed on both side surfaces of the transfer frame 300. The chambers 400 and 700 disposed on a side surface and the other side surface of the transfer frame 300 may have an arrangement of A×B (A and B are natural numbers greater than 1 or 1 respectively) along the first direction 2 and the third direction 6, respectively.

The transfer frame 300 has a transfer robot 320 and a transfer rail 324. The transfer robot 320 transfers the substrate M. More specifically, the transfer robot 320 transfers the substrate M between the buffer unit 200 and the chambers 400 and 700. In addition, the transfer robot 320 transfers the substrate M between the chambers 400 and 700. The transfer robot 320 has a plurality of hands 322 on which the substrate M is placed. The hand 322 may forwardly and backwardly move, rotate around the third direction 6 as an axis, and move along the third direction 6. The plurality of hands 322 may be disposed to be spaced apart parallel to the third direction 6 and may move independently of each other.

The transfer rail 324 is positioned in the transfer frame 300 and is formed in a direction horizontal to the lengthwise direction of the transfer frame 300. The transfer robot 320 is placed on the transfer rail 324, and the transfer robot 320 may forwardly and backwardly move along the transfer rail 324.

An object to be treated in the chambers 400 and 700 may be a substrate of any one of a wafer, a glass, and a photomask. The substrate treated in the chambers 400 and 700 according to an embodiment may be a photo mask which is a ‘frame’ used in an exposing process. The substrate M according to an embodiment may have a rectangular shape. A reference mark AK, a first pattern P1, and a second pattern P2 may be formed on the substrate M.

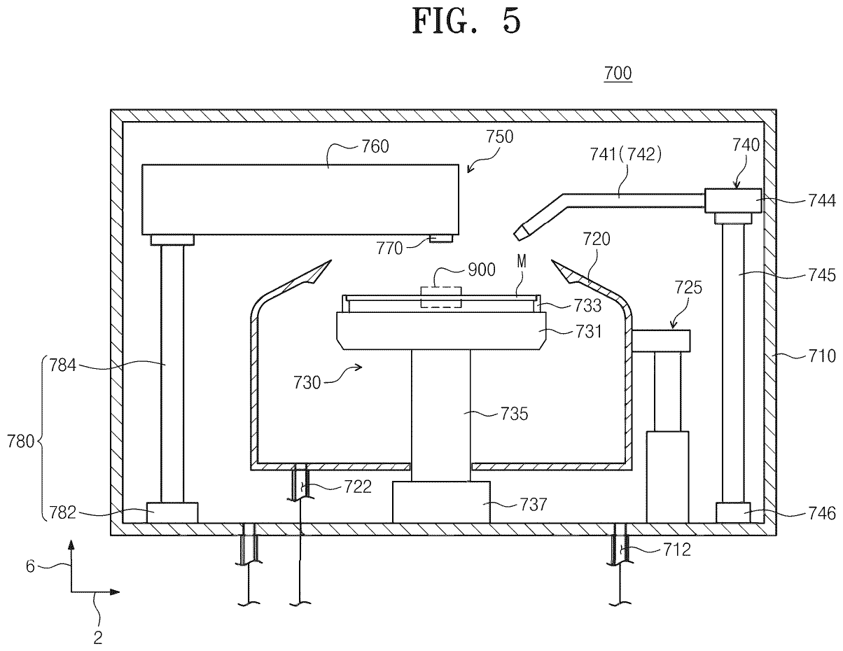

At least one reference mark AK may be formed on the substrate M. For example, the reference mark AK is a number corresponding to the number of corners of the substrate M, and may be formed in a corner region of the substrate M. The reference mark AK may be used to align the substrate M. More specifically, the reference mark AK may be used to determine whether the substrate M is twisted in a process of supporting the substrate M in a second support unit 530 (see FIG. 5), which will be described later. In addition, the reference mark AK may be a mark used to check position information of the substrate M. More specifically, the reference mark AK may be a mark used to check a position information on a plurality of patterns formed on the substrate M. Accordingly, the reference mark AK may be defined as a so-called align key.

At least one cell CE may be formed on the substrate M. The plurality of patterns are formed in each of the plurality of cells CE. The patterns formed in each cell CE include an exposure pattern EP and a first pattern P1. The patterns formed in each cell CE may be defined as one pattern group.

The exposure pattern EP may be used to form an actual pattern on the substrate M. The first pattern P1 may be a pattern representing the exposure patterns EP formed in one cell CE. If the plurality of cells CE are formed on the substrate M, there may also be a plurality of first patterns P1 formed on the cell CE. That is, first patterns P1 may be formed in each of a plurality of cells CE. However, the inventive concept is not limited thereto, and the plurality of first patterns P1 may be formed in one cell CE.

The first pattern P1 may have a shape in which some of the exposure patterns EP are combined. The first pattern P1 may be defined as a so-called monitoring pattern. An average value of critical dimensions of the plurality of first patterns P1 may be defined as a critical dimension monitoring macro (CDMM).

If an operator inspects the first pattern P1 formed in any one cell CE through a scanning electron microscope (SEM), whether the shape of the exposure patterns EP formed in any one cell CE are good or bad may be estimated. Accordingly, the first pattern P1 may function as an inspection pattern. Unlike the above-described example, the first pattern P1 may be any one of the exposure patterns (EP) participating in an actual exposing process. Selectively, the first pattern P1 may be an inspection pattern and may be a pattern participating in an actual exposing process at the same time.

A second pattern P2 is formed outside the cells CE formed on the substrate M. That is, the second pattern P2 is formed in an outer region of a region in which the plurality of cells CE are formed. The second pattern P2 may be a pattern representing the exposure patterns EP formed on the substrate M. The second pattern P2 may be defined as an anchor pattern. A plurality of second patterns P2 may be formed outside the cells CE. The plurality of second patterns P2 may be arranged in a combination of series and/or parallel. That is, the plurality of second patterns P2 may be aligned in a combination of any one row and any one column. For example, five second patterns P2 may be formed on the substrate M, and the five second patterns P2 may be arranged in a combination of two columns and three rows. However, this is an example, and a combination of the second patterns P2 may be variously modified.

If the operator inspects the second pattern P2 through a scanning electron microscope (SEM), it is possible to estimate whether the shape of the exposure patterns EP formed on one substrate M are good or bad. Accordingly, the second pattern P2 may function as an inspection pattern. The second pattern P2 may be an inspection pattern which does not participate in an actual exposing process. In addition, the second pattern P2 may be a pattern for setting process conditions of the exposure apparatus.

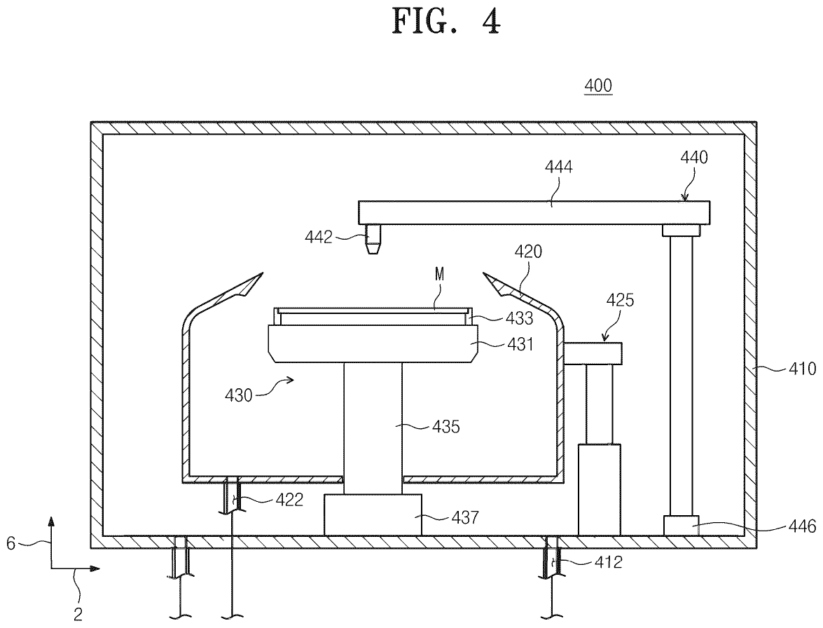

FIG. 4 is a cross-sectional view schematically illustrating the first chamber according to an embodiment.

The first chamber 400 according to an embodiment of the inventive concept may perform a predetermined process on the substrate M. The process performed on the first chamber 400 may be a hydrophilization process of hydrophilizing the substrate M which has been hydrophobized in the previous treating process. The first chamber 400 may include a first housing 410, a first treating container 420, a first support unit 430, and a first liquid supply unit 440.

The first housing 410 may have a substantially rectangular parallelepiped shape. The first housing 410 has an inner space. The first treating container 420, the first support unit 430, and the first liquid supply unit 440 are disposed at the inner space of the first housing 410. An entrance (not shown) through which the substrate M enters and exits is formed on a sidewall of the first housing 410. In addition, a first exhaust line 412 may be connected to a bottom of the first housing 410. A pump (not shown) is installed in the first exhaust line 412 so that an inner pressure of the first housing 410 may be adjusted. Also, foreign substances drifting in the inner space of the first housing 410 may be discharged to an outside of the first housing 410 through the first exhaust line 412.

The first treating container 420 may be a bowl with an open top portion. The first treating container 420 may surround an outside of a first body 431 and a first support shaft 435 to be described later. The first treating container 420 generally has a ring shape. In addition, a first discharge line 422 is connected to a bottom of the first treating container 420. The first discharge line 422 may recollect a liquid collected in the first treating container 420. The liquid recollected by the first discharge line 422 may be reused at a regeneration system which is not shown. In addition, the first treating container 420 is coupled to a first container driver 425. The first container driver 425 moves the first treating container 420 in an up/down direction. According to an embodiment, the first container driver 425 may be any one among known motors.

The first support unit 430 supports and rotates the substrate M. The first support unit 430 may include a first body 431, a first support shaft 435, and a first shaft driver 437.

A top surface of the first body 431 has a substantially circular shape when seen from above. Also, the top surface of the first body 431 has a diameter larger than that of the substrate M. A first support pin 433 is disposed at a top end of the first body 431. The first support pin 433 upwardly protrudes from the top surface of the first body 431. Also, the first support pin 433 may be configured in a plurality. For example, there may be four first support pins 433. Each of the plurality of first support pins 433 may each be disposed in each corner region of the substrate M having a rectangular shape.

Also, the first support pin 433 may have a first surface and a second surface. For example, the first surface may support a bottom end of the corner region of the substrate M, and the second surface may support a side end of the corner region of the substrate M. Accordingly, if the substrate M rotates, the second surface may restrict a separation of the substrate M toward a side.

The first support shaft 435 has a lengthwise direction parallel to the third direction 6. The first support shaft 435 may be inserted into a groove formed at a bottom of the first treating container 420. An end of the first support shaft 435 is coupled to a bottom end of the first body 431, and the other end thereof is coupled to the first shaft driver 437. The first shaft driver 437 rotates the first support shaft 435 in the third direction 6 as an axis. Accordingly, the first body 431 and the substrate M are also rotated. In addition, the first shaft driver 437 may lift and lower the first body 431 in the third direction 6.

The first liquid supply unit 440 supplies the first liquid to the substrate M supported by the first support unit 430. According to an embodiment, the first liquid may include an acid. More specifically, the first liquid may include a sulfuric acid H₂SO₄. For example, the first liquid may be a sulphuric peroxide mixture (SPM) liquid. More specifically, the SPM liquid may be a liquid in which an acid and a hydrogen peroxide (H₂O₂) are mixed. However, the inventive concept is not limited thereto, and the first liquid may include various known liquids for hydrophilizing a surface of a hydrophobized substrate M.

The first liquid supply unit 440 may include a first nozzle 442 and a first nozzle arm 444.

The first nozzle 442 supplies the first liquid to the substrate M. Unlike shown in FIG. 4, there may be a plurality of first nozzles 442. The plurality of first nozzles 442 may supply a first liquid having different composition ratios to the substrate M. In addition, the plurality of first nozzles 442 may supply different types of first liquids to the substrate M.

The first nozzle arm 444 supports the first nozzle 442. A first nozzle 442 is installed at an end of the first nozzle arm 444, and a first arm driver 446 is coupled to the other end thereof. The first arm driver 446 changes a position of the first nozzle arm 444 with the third direction 6 as an axis. Accordingly, a position of the first nozzle 442 may be changed.

In addition to the above-described example, the first liquid supply unit 440 may further supply a rinsing liquid to the substrate M. The rinsing liquid according to an embodiment may be a deionized water or a deionized carbon dioxide water obtained by adding carbon dioxide to the deionized water. If further supplying the rinsing liquid to the substrate M, it is preferable to supply the first liquid to the substrate M in advance to hydrophilize the substrate M and then subsequently supply the rinsing liquid to the substrate M.

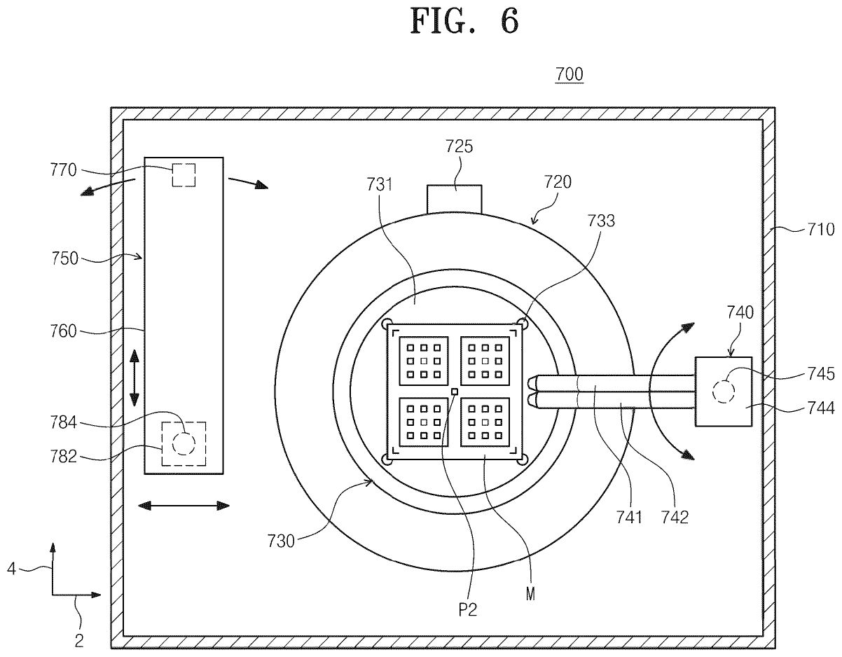

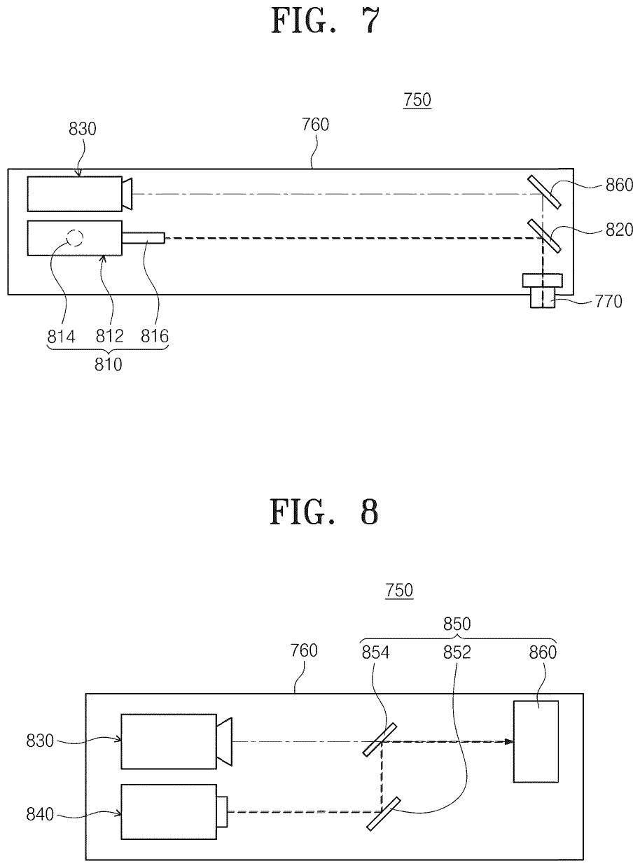

FIG. 5 is a cross-sectional view schematically illustrating a second chamber according to an embodiment. FIG. 6 is a cross-sectional view schematically illustrating the second chamber seen from above according to an embodiment. FIG. 7 is a cross-sectional view of an optical module according to an embodiment, seen from a side. FIG. 8 is a cross-sectional view of the optical module according to an embodiment seen from above.

Hereinafter, a second chamber according to an embodiment of the inventive concept will be described with reference to FIG. 5 to FIG. 8.

The second chamber 700 performs a predetermined process on the substrate M. More specifically, a process performed in the second chamber 700 may be a Fine Critical Dimension Correction (FCC) during a mask manufacturing process for an exposing process. That is, in the second chamber 700, a specific pattern (e.g., a second pattern P2) among a plurality of patterns formed on the substrate M may be etched. In addition, the substrate M treated in the second chamber 700 may be a substrate M on which a pre-treatment is performed. For example, the Fine Critical Dimension Correction process according to an embodiment may be performed after the hydrophilization process performed in the first chamber 400. In addition, the critical dimensions of the first pattern P1 and the second pattern P2 formed on the substrate M taken into the second chamber 700 may be different from each other. According to an embodiment, a critical dimension of the first pattern P1 may be relatively greater than a critical dimension of the second pattern P2. For example, the critical dimension of the first pattern P1 may have a first width (e.g., 69 nm), and the critical dimension of the second pattern P2 may have a second width (e.g., 68.5 nm).

The second chamber 700 may include a second housing 710, a second treating container 720, a second support unit 730, a second liquid supply unit 740, an optical module 750, and a contact angle measuring unit 900.

The second housing 710 may have a substantially hexahedral shape. The second housing 710 has an inner space. The second treating container 720, the second support unit 730, the second liquid supply unit 740, and the optical module 750 are placed in the inner space of the second housing 710.

An entrance (not shown) is formed on a sidewall of the second housing 710. The substrate M is taken in and out of the second housing 710 through the entrance (not shown). In addition, the entrance (not shown) is opened and closed by a door assembly which is not shown. An inner wall surface of the second housing 710 may be coated with a material having a high corrosion resistance to an etchant to be described later. In addition, an exhaust hole is formed at a bottom of the second housing 710, and a second exhaust line 712 is connected to the exhaust hole. A pump (not shown) for applying a negative pressure to an inner space of the second housing 710 is installed in the second exhaust line 712. If the pump (not shown) provides the negative pressure, an atmosphere of the inner space of the second housing 710 is exhausted. In addition, the foreign substances generated in a process of treating the substrate M are discharged to an outside of the second housing 710 through the second exhaust line 712.

The second treating container 720 can prevent the second liquid supplied to the substrate M from being scattered to the second housing 710, the second liquid supply unit 740, and the optical module 750. The second treating container 720 may be a bowl having an open top portion. The second treating container 720 may have a shape surrounding at least a portion of the second support unit 730.

A groove into which the second support shaft 735 to be described later is inserted is formed at a bottom of the second treating container 720. In addition, the second discharge line 722 which discharges the second liquid supplied by the second liquid supply unit 740 to the outside is connected to the bottom of the second treating container 720. The second liquid discharged to the outside through the second discharge line 722 may be reused by an outer regeneration system (not shown).

A side surface of the second treating container 720 may upwardly extend from a bottom surface of the second treating container 720. In addition, a top portion of the second treating container 720 may be formed to be inclined. For example, the top portion of the second treating container 720 may upwardly extend with respect to the ground toward the substrate M supported by the second support unit 730.

The second treating container 720 may be coupled to the second container driver 725. The second container driver 725 may lift and lower the second treating container 720 in a direction parallel to the third direction 6. The second container driver 725 may upwardly move the second treating container 720 while the substrate M is liquid-treated or heated. In this case, a top end of the second treating container 720 may be positioned higher than a top end of the substrate M supported by the second support unit 730. On the other hand, if the substrate M is taken into the inner space of the second housing 710, or if the substrate M is taken out of the inner space of the second housing 710, the second container driver 725 may downwardly move the second treating container 720. In this case, the top end of the second treating container 720 may be positioned below the top end of the substrate M supported by the second support unit 730.

The second support unit 730 supports and rotates the substrate M. The second support unit 730 may include a second body 731, a second support pin 733, a second support shaft 735, and a second shaft driver 737. The second body 731, the second support pin 733, the second support shaft 735, and the second shaft driver 737, respectively, have the same or similar structures as the first body 431, the first support pin 433, the first support shaft 435, and the first shaft driver 437, so repeated explanations are omitted.

The second liquid supply unit 740 supplies the second liquid to the substrate M. In addition, the second liquid supply unit 740 supplies the rinsing liquid to the substrate M. The second liquid according to an embodiment may be an etchant, which is a type of an etchant which etches patterns formed on the substrate M. In addition, the rinsing liquid according to an embodiment may be a deionized water or a deionized carbon dioxide water.

The second liquid supply unit 740 may include second nozzles 741 and 742. The second nozzles 741 and 742 may include a 2-1 nozzle 741 and a 2-2 nozzle 742. The 2-1 nozzle 741 may supply the etchant to the substrate M supported by the second support unit 730. In addition, the 2-2 nozzle 742 may supply the rinsing liquid to the substrate M supported by the second support unit 730. Unlike the above-described example, three or more nozzles included in the second liquid supply unit 740 may be provided. A plurality of nozzles may supply different types of liquids to the substrate M supported by the second support unit 730. In addition, some of the plurality of the nozzles may supply the same type of liquid to the substrate M, but may supply a liquid with different composition ratios to the substrate M.

An end of the second nozzle 741 and 742 is coupled to the fixing body 744, and the other end extends away from the fixing body 744. In FIG. 5 and FIG. 6, the other end of the second nozzle 741 and 742 is illustrated to be inclined at a predetermined angle in a direction toward the substrate M supported by the second support unit 730, but the inventive concept is not limited thereto. For example, the second nozzles 741 and 742 and the fixing body 744 may be coupled to each other by a hinge. In this case, angles of the second nozzles 741 and 742 with respect to the substrate M may be variously changed.

The fixing body 744 is coupled to the rotation shaft 745 having a lengthwise direction parallel to the third direction 6. An end of the rotation shaft 745 is coupled to the fixing body 744, and the other end is coupled to the rotation driver 746. The rotation driver 746 rotates the rotation shaft 745 with the third direction 6 as an axis. Accordingly, the second nozzles 741 and 742 may also be rotated on a horizontal plane and their positions may be changed.

The optical module 750 may include an optical cover 760, a head nozzle 770, a moving unit 780, a laser unit 810, an imaging unit 830, and a lighting unit 840.

The optical cover 760 has an installation space therein. The installation space of the optical cover 760 has an environment sealed from the outside. Inside the optical cover 760, a portion of the head nozzle 770, the laser unit 810, the imaging unit 830, and the lighting unit 840 are disposed. The head nozzle 770, the laser unit 810, the imaging unit 830, and the lighting unit 840 are modularized by the optical cover 760.

An opening is formed in a bottom portion of the optical cover 760. A portion of the head nozzle 770 is inserted into the opening formed in the optical cover 760. Accordingly, the head nozzle 770 is positioned so that a portion of the head nozzle 770 downwardly protrudes from a bottom end of the optical cover 760. The head nozzle 770 may include an objective lens and a barrel. The laser unit 810 to be described later irradiates a laser to the substrate M through a head nozzle 770. In addition, the imaging unit 830 to be described later acquires an image of the substrate M through the head nozzle 770.

The moving unit 780 is coupled to the optical cover 760. The moving unit 780 moves the optical cover 760. The moving unit 780 includes a shaft driver 782 and a shaft 784. The shaft 784 has a lengthwise direction parallel to the third direction 6. An end of the shaft 784 is coupled to the bottom end of the optical cover 760, and the other end of the shaft 784 is connected to the shaft driver 782.

According to an embodiment, the shaft driver 782 may be a motor. The shaft driver 782 may rotate the shaft 784 with the third direction 6 as an axis. In addition, the shaft driver 782 may be composed of a plurality of motors. For example, any one of the plurality of motors can rotate the shaft 784, the other can lift and lower the shaft 784 in the third direction 6, and the other can be mounted on a guide rail which is not shown to forwardly and backwardly move the shaft 784 in the first direction 2 or the second direction 4. A position of the optical cover 760 is changed by the shaft driver 782, and a position of the head nozzle 770 is also changed.

The laser unit 810 irradiates the substrate M with a laser. The laser unit 810 irradiates the laser to a specific region of the substrate M to locally heat the specific region. The specific region according to an embodiment may be a region in which the second pattern P2 is formed.

The laser unit 810 may include an oscillation unit 812 and an expander 816. The oscillation unit 812 oscillates a laser. An output of the laser oscillated from the oscillation unit 812 may be adjusted according to process requirements. In addition, a tilting member 814 may be installed in the oscillation part 812. The tilting member 814 may change an oscillation direction of the laser oscillating from the oscillating unit 812 by adjusting an arrangement angle of the oscillating unit 812.

The expander 816 may include a plurality of lenses which are not shown. The expander 816 adjusts an interval between the plurality of lenses to change an emission angle of the laser oscillated from the oscillation unit 812. Accordingly, the expander 816 may adjust a profile of the laser irradiated to the substrate M by expanding or reducing a diameter of the laser. The expander 816 according to an embodiment may be a variable beam expander telescope (BET). The laser adjusted by the expander 816 to a predetermined profile is transferred to the bottom reflective plate 820.

The bottom reflective plate 820 is positioned on a moving path of the laser oscillated from the oscillation unit 812. In addition, the bottom reflective plate 820 is positioned to overlap the head nozzle 770 when seen from above. In addition, the bottom reflective plate 820 may be tilted at a certain angle so that the laser emitted from the oscillation part 812 is transmitted to the head nozzle 770. Accordingly, the laser emitted from the oscillation part 812 is irradiated to the second pattern P2 through the expander 816, the bottom reflective plate 820, and the head nozzle 770 sequentially.

The imaging unit 830 acquires an image of the substrate M by imaging the substrate M. The image according to an embodiment may be a photo or a video. The imaging unit 830 may be an automatic focus camera module in which a focus is automatically adjusted. The lighting unit 840 provides a lighting to the substrate M so that the imaging unit 830 may more easily acquire the image of the substrate M.

The top reflective unit 850 may include a first reflective plate 852, a second reflective plate 854, and a top reflective plate 860.

The first reflective plate 852 and the second reflective plate 854 are installed at a height corresponding to each other. The first reflective plate 852 changes a lighting direction of the lighting unit 840. For example, the first reflective plate 852 reflects a lighting in a direction toward the second reflective plate 854. In addition, the second reflective plate 854 reflects the lighting again to the top reflective plate 860.

The top reflective plate 860 is disposed to overlap the bottom reflective plate 820 when seen from above. In addition, the top reflective plate 860 is disposed above the bottom reflective plate 820. In addition, the top reflective plate 860 may be tilted at a same angle as the bottom reflective plate 820. Accordingly, the imaging unit 830 may acquire an image of the substrate M through the top reflective plate 860 and the head nozzle 770. In addition, the lighting unit 840 can provide a lighting to the substrate M through the first reflective plate 852, the second reflective plate 854, the top reflective plate 860, and the head nozzle 770. That is, an irradiation direction of the laser irradiated to the substrate M, an imaging direction of acquiring the image of the substrate M, and the lighting direction provided to the substrate M are coaxial with each other.

A contact angle measuring unit 900 may measure a contact angle between a droplet discharged to the substrate M and the substrate M. The contact angle measuring unit 900 may be installed on a sidewall of the second housing 710. In addition, the contact angle measuring unit 900 may be installed at a height corresponding to the substrate M. Accordingly, the contact angle measuring unit 900 may measure the contact angle between the droplet and the substrate M at a side of the substrate M. The contact angle measuring unit 900 may be one of droplets supplied to an object and a known camera capable of optically measuring the angle formed by the object.

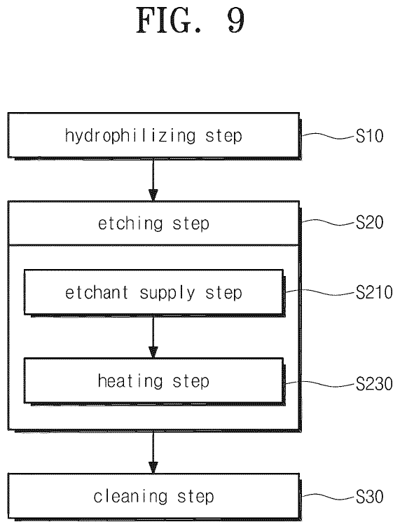

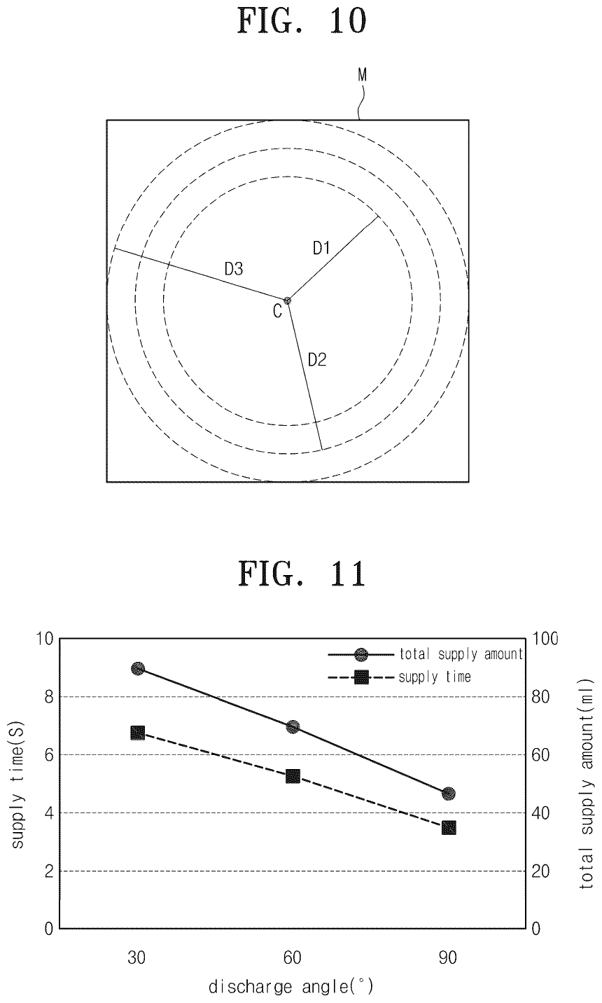

FIG. 9 is a flowchart of a substrate treating method according to an embodiment. FIG. 10 is a graph schematically illustrating a supply position of a second liquid on the substrate according to an embodiment. FIG. 11 is a graph showing correlations between the supply position of the second liquid, a discharge angle of the second liquid, a supply amount of the second liquid, and a supply time of the second liquid according to an embodiment.

Hereinafter, a substrate treating method according to an embodiment of the inventive concept will be described with reference to FIG. 9 to FIG. 11. Since the substrate treating method described below is performed in the substrate treating apparatus 1 described above, the reference codes cited in FIG. 2 to FIG. 8 are cited in the same way below. In addition, the substrate treating method according to an embodiment may be performed by controlling configurations included in the substrate treating apparatus 1 by the above-described controller 30.

The substrate treating method according to an embodiment may include a hydrophilizing step S10, an etching step S20, and a cleaning step S30. According to an embodiment, the hydrophilizing step S10, the etching step S20, and the cleaning step S30 may be performed in the order of time series.

The hydrophilizing step S10 may be performed in the first chamber 400. In the hydrophilizing step S10, a first liquid is supplied to the substrate M. Accordingly, the hydrophilizing step S10 may be referred to as a first liquid supply step. In the hydrophilizing step S10, a hydrophobized substrate M may be hydrophilized. That is, in the hydrophilizing step S10, a surface of the hydrophobized substrate M is hydrophilized to improve a reactivity between the substrate M and the etchant in a subsequent etching step S20.

In the hydrophilizing step S10, the first liquid is supplied to a rotating substrate M. Accordingly, the first liquid may be uniformly coated on to the entire region of the substrate M to hydrophilize the surface of the substrate M. In addition, after supplying the first liquid to the substrate M, the rinsing liquid may be further supplied to the substrate M. The rinsing liquid supplied to the substrate M may clean the substrate M by replacing the first liquid remaining on the substrate M.

When the hydrophilizing step S10 is completed, the substrate M is transferred from the first chamber 400 to the second chamber 700 by a transfer robot 320. When the substrate M is transferred to the second chamber 700, the etching step S20 is performed. That is, the etching step S20 may be performed in the second chamber 700. A process of treating the substrate M in the etching step S20 may be the aforementioned Fine Critical Dimension Correction (FCC). The etching step S20 etches a specific region of the substrate M. More specifically, the etching step S20 locally etches a region in which the second pattern P2 is formed among the first pattern P1 and the second pattern P2 formed on the substrate M.

The etching step S20 according to an embodiment may include an etchant supply step S210 and a heating step S230. The etchant supply step S210 and the heating step S230 may be sequentially performed.

In the etchant supply step S210, the etchant, which is the second liquid, is supplied to the substrate M. Accordingly, the etchant supply step S210 may be referred to as a second liquid supply step. In the etchant supply step S210, the etchant may be supplied to the substrate M which rotation is stopped. If the etchant is supplied to a substrate M which rotation has stopped, the etchant may be supplied in an amount sufficient to form a liquid film or a puddle. For example, an amount of etchant supplied to the substrate M covers an entire top surface of the substrate M, but the etchant may be supplied so the etchant does not flow down from the substrate M, or even if the etchant flows down from the substrate M, the amount may not be large.

According to an embodiment, before performing the etchant supply step S210, the second liquid supply unit 740 may discharge the second liquid for testing to the substrate M. The second liquid for testing forms droplets on the substrate M. Subsequently, the contact angle measuring unit 900 measures an angle formed between the substrate M and droplets. That is, the contact angle measuring unit 900 measures a contact angle between the substrate M and droplets. A data on a measured contact angle is transmitted to the controller 30, and the controller 30 determines a degree of hydrophilization of the substrate M based on the transmitted data. For example, as the measured contact angle is smaller, it may be determined that the degree of hydrophilization of the substrate M is greater.

Based on a determined degree of hydrophilization of the substrate M, a supply mechanism of the etchant supplied to the substrate M can be determined at the etchant supply step S210 described above. The supply mechanism of the etchant can be determined by a combination of at least one of a supply position of the etchant supplied to the substrate M, a supply time of the etchant supplied to the substrate M, and a discharge angle of the etchant. That is, the etchant supply mechanism according to an embodiment can be determined by changing at least one factor among the supply position of the etchant supplied to the substrate M, the supply time of the etchant supplied to the substrate M, and the discharge angle of the etchant.

Based on the degree of hydrophilization of the substrate M, the supply time of the etchant supplied to the substrate M may be determined. In other words, assuming that the etchant is supplied at a same flow rate per unit time, if the degree of hydrophilization of the substrate M which has completed the hydrophilizing step S10 is low, a supply time of the etchant supplied to the substrate M can be increased. On the contrary, if the degree of hydrophilization of the substrate M is high, the supply time of the etchant supplied to the substrate M may be reduced.

The supply position of the etchant supplied to the substrate M may mean a position at which the etchant is supplied based on a center C of the substrate M. For example, the etchant may be supplied to a first position spaced apart from the center of the substrate M by a first distance D1. In addition, the etchant may be supplied to a second position spaced apart from the center of the substrate M by a second distance D2. In addition, the etchant may be supplied to a third position spaced apart from the center of the substrate M by a third distance D3. According to an embodiment, the first distance D1 may have a value smaller than the second distance D2, and the second distance D2 may have a value smaller than the third distance D3. That is, the first position may be a position closer to the center of the substrate M than the third position.

In addition, the discharge angle of the etchant may be an angle of the 2-1 nozzle 741 with respect to the top surface of the substrate M. For example, if the top surface of the substrate M is positioned in a horizontal direction with respect to the ground and the second nozzles 741 and 742 are formed at an angle in a direction perpendicular to the ground, the discharge angle of the etchant may be 90 degrees. In addition, if the top surface of the substrate M is positioned horizontally with respect to the ground and the second nozzles 741 and 742 are formed at an angle downwardly inclined with respect to the ground toward the substrate M, the discharge angle of the etchant may be less than 90 degrees. For example, if the angle between the substrate M and the second nozzles 741 and 742 is 90 degrees, the discharge angle of the etchant may be defined as a first angle. In addition, if the angle between the substrate M and the second nozzles 741 and 742 is 60 degrees, the discharge angle of the etchant may be defined as a second angle. In addition, if the angle between the substrate M and the second nozzles 741 and 742 is 30 degrees, the discharge angle of the etchant may be defined as a third angle.

As described above, in the etchant supply step S210, the etchant is supplied to a non-rotating substrate M. Therefore, the closer the supply position of the etchant is from the center of the substrate M, the less time it takes for the etchant to be coated to the entire region of the substrate M, based on a same flow rate and a same discharge time. Accordingly, the etchant supply position acts as an important factor from a perspective of throughput.

In addition, in order to coat the etchant to the entire region of the substrate M, the larger the discharge angle of the etchant, the closer it must be to the center of the substrate M. On the contrary, in order to uniformly coat the etchant to the entire region of the substrate M, the smaller the discharge angle of the etchant, the closer it must be to an edge of the substrate M. For example, if the discharge angle of the etchant is the first angle (e.g., 90 degrees), the etchant must be discharged at the first position adjacent to the center C of the substrate M so that the etchant can be uniformly coated to the entire region of the substrate M. In addition, if the discharge angle of the etchant is the third angle (e.g., 30 degrees), the etchant must be coated to the third position adjacent to the edge of the substrate M so that the etchant can be uniformly coated to the entire region of the substrate M. As described in FIG. 11, if the discharge angle of the etchant is the first angle and the supply position of the etchant is the first position, both the supply time of the etchant for coating the entire region of the substrate M and the supply amount of the etchant are smaller than when the discharge angle of the etchant is the third angle and the supply position of the etchant is the third position.

Accordingly, according to an embodiment of the inventive concept, factors of the supply position of the etchant, the discharge angle of the etchant, and the supply time of the etchant can be modified in various combinations, and may determine a supply mechanism of the etchant supplied to the substrate M, based on a degree of hydrophilization of the substrate M. The discharge angle of the etchant and the supply position of the etchant illustrated above are merely illustrations for convenience of explanation, and the scope of the inventive concept is not limited to the above.

That is, according to the above-described example, the discharge angle of the etchant may be adjusted according to the supply position of the etchant so the supply mechanism of the etchant can be changed. In addition, the supply position of the etchant may be adjusted based on the discharge angle of the etchant so the supply mechanism can be changed. In addition, the supply mechanism may be changed by adjusting the supply time of the etchant based on the discharge angle of the etchant. Other than this, the above-mentioned factors in various combinations may be change the supply mechanism of the etchant based on the degree of hydrophilization of the substrate M. For example, if the degree of hydrophilization of the substrate M is low, the supply position of the etchant may move to the first position (a position adjacent to the center of the substrate M). In addition, if the degree of hydrophilization of the substrate M is low, the discharge angle of the etchant may be increased.

In the heating step S230, the substrate M is heated. More specifically, the optical module 750 irradiates the laser to a specific region of the substrate M at which the liquid film is formed (e.g., a region at which the second pattern P2 is formed). The second pattern is locally heated by the irradiated laser. Accordingly, the region in which the second pattern is formed may have a degree of etching which is relatively greater than other regions on the substrate M.

By the laser locally irradiated to the second pattern P2, the critical dimension of the first pattern P1 may change from the first critical dimension (e.g., 69 nm) to the target critical dimension (e.g., 70 nm). In addition, the critical dimension of the second pattern P2 may change from the second critical dimension (e.g., 68.5 nm) to the target critical dimension (e.g., 70 nm). That is, in the etching step S20, an etching ability of the substrate M for the specific region may be improved, thereby minimizing a critical dimension deviation of the patterns formed on the substrate M.

In the cleaning step S30, the substrate M is cleaned. More specifically, in the cleaning step S30, the rinsing liquid is supplied to a rotating substrate M. The rinsing liquid supplied to the substrate M removes etching foreign substances generated in a process of performing the etching step S20 from the substrate M. In addition, the rinsing liquid cleans the substrate M by replacing the liquid film formed on the substrate M.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating method comprising:
supplying a liquid to a substrate; and
heating the substrate after the supplying the liquid, and
wherein the supplying the liquid includes:
supplying a first liquid to the substrate; and
supplying a second liquid which is different from the first liquid to a substrate to which the first liquid is supplied, and
wherein the second liquid is supplied as a test to the substrate and a contact angle between the second liquid which is supplied and the substrate is measured to determine a degree of hydrophilization of the substrate, and a supply mechanism of the second liquid supplied to the substrate is determined based on the degree of hydrophilization of the substrate which is determined, before the supplying the second liquid is performed.

2. The substrate treating method of claim 1, wherein the supply mechanism includes at least one of a supply time of the second liquid supplied to the substrate, a supply position of the second liquid supplied to the substrate, or a discharge angle of the second liquid.

3. The substrate treating method of claim 2, wherein the discharge angle of the second liquid is changed depending on an angle of a nozzle with respect to a top surface of the substrate, and
the discharge angle of the second liquid is adjusted according to the supply position of the second liquid to change the supply mechanism.

4. The substrate treating method of claim 3, wherein the supply time of the second liquid is adjusted depending on the discharge angle of the second liquid to change the supply mechanism.

5. The substrate treating method of claim 1, wherein the supplying the first liquid supplies the first liquid to the substrate to hydrophilize a hydrophobized substrate.

6. The substrate treating method of claim 1, wherein the substrate is a mask, and
the mask has a first pattern which is formed within a plurality of cells and a second pattern which is formed outside of a region at which the cells are formed, and
the heating the substrate includes heating the second pattern between the first pattern and the second pattern by irradiating a laser to the second pattern.

7. The substrate treating method of claim 6, wherein a critical dimension of the first pattern is larger than a critical dimension of the second pattern, before the second liquid is supplied to the substrate.

8. The substrate treating method of claim 7, wherein the critical dimension of the first pattern and the critical dimension of the second pattern match within an error range, after the heating the substrate.

9. The substrate treating method of claim 1, wherein a chamber suppling the first liquid and a chamber supplying the second liquid are different from each other.

10. The substrate treating method of claim 1, wherein the second liquid is supplied to a substrate which has stopped rotating in the supplying the second liquid.

11. The substrate treating method of claim 1 further comprising supplying a rinsing liquid to a rotating substrate to clean the substrate.

12. The substrate treating method of claim 1, wherein the first liquid includes a sulfuric acid,
and the second liquid includes an etchant for etching a pattern formed on the substrate.

13. A mask treating method comprising:
hydrophilizing a mask by supplying a first liquid;
etching a specific region of the mask; and
cleaning the mask, and
wherein the etching the specific region includes:
supplying a second liquid which is different from the first liquid to the mask; and
heating the specific region by irradiating a laser to the specific region of the mask to which the second liquid is supplied, and
wherein a supply mechanism of the second liquid which is supplied to the mask is determined based on a contact angle between the second liquid which is supplied to the mask and the mask, at the supplying the second liquid.

14. The mask treating method of claim 13, wherein the supply mechanism includes a supply time of the second liquid supplied to the mask, a supply position of the second liquid supplied to the mask, and/or a discharge angle of the second liquid.

15. The mask treating method of claim 14, wherein a degree of hydrophilization of the mask is determined based on the contact angle, and as the degree of hydrophilization which is determined is smaller, the supply time of the second liquid increases to change the supply mechanism.

16. The mask treating method of claim 14, wherein a degree of hydrophilization of the mask is determined based on the contact angle, and as the degree of hydrophilization which is determined is smaller, the supply position of the second liquid is moved toward a center of the mask to change the supply mechanism.

17. The mask treating method of claim 14, wherein a degree of hydrophilization of the mask is determined based on the contact angle, and as the degree of hydrophilization which is determined is smaller, the discharge angle of the second liquid is increased to change the supply mechanism.

18. The mask treating method of claim 13, wherein the mask has a first pattern which is formed within a plurality of cells and a second pattern which is formed outside of a region at which the cells are formed, and
the heating the specific region includes heating the second pattern between the first pattern and the second pattern by irradiating a laser to the second pattern.

19. The mask treating method of claim 18, wherein a critical dimension of the first pattern is larger than a critical dimension of the second pattern before the etching the specific region, and
the critical dimension of the first pattern corresponds to the critical dimension of the second pattern after the etching the specific region.

20. A substrate treating method for treating a substrate having a first pattern and a second pattern which is different from the first pattern, the substrate treating method comprising:
supplying a first liquid to the substrate to hydrophilize the substrate;
supplying a second liquid to the substrate;
locally heating the second pattern by irradiating a laser to the second pattern; and
supplying a rinsing liquid to the substrate, and
wherein the supplying the first liquid is performed in a first chamber,
the supplying the second liquid, the locally heating the second pattern, and the supplying the rinsing liquid are performed at a second chamber which is different from the first chamber,
a critical dimension of the first pattern is larger than a critical dimension of the second pattern before the supplying the second liquid, and the second pattern is etched so the critical dimension of the first pattern and the critical dimension of the second pattern are matched within an error range after the locally heating the second pattern,
the second liquid is supplied as a test to the substrate and a contact angle between the second liquid which is supplied and the substrate is measured to determine a degree of hydrophilization of the substrate, and a supply mechanism of the second liquid supplied to the substrate is determined based on the degree of hydrophilization of the substrate which is determined, before the supplying the second liquid is performed, and
the supply mechanism includes at least one of a supply time of the second liquid supplied to the substrate, a supply position of the second liquid supplied to the substrate, or a discharge angle of the second liquid.
